(19) United States
(12) Patent Application Publication
(10) Pub. No.: US 2004/0160174 A1
(43) Pub. Date: Aug. 19, 2004

(54) Active matrix organic electro-luminescence display

(76) Inventor: Hsin-Hung Lee, Taipei (TW)

Correspondence Address: J.C. Patents, Inc., Suite 250, 4 Venture, Irvine, CA, 92618, US

(21) Appl. No.: 10/423,651

(22) Filed: Apr. 24, 2003

(30) Foreign Application Priority Data
Feb. 19, 2003 (TW) 92103362

(51) Int. Cl. H05B 33/00

(52) U.S. Cl. 313/506; 313/500; 313/504

(57) ABSTRACT

An active matrix organic electro-luminescence display (OELD) device is provided. The OELD device comprises a substrate, a thin film transistor array, a dielectric layer, an organic functional layer and a cathode layer. The thin film transistor array furthermore comprises a plurality of thin film transistors, a plurality of anodes corresponding to each thin film transistor and a plurality of scan lines and data lines formed on the substrate. The dielectric layer is formed over the substrate. The dielectric layer covers the edges of all the anodes within the thin film transistor array. The organic functional layer is formed over the thin film transistor array and the dielectric layer. The cathode layer is formed over the organic functional layer. Because a dielectric layer covers the edges of the anodes entirely, the anodes are prevented from short-circuiting with the cathode layer.

### CROSS-REFERENCE TO RELATED APPLICATION

This application claims the priority benefit of Taiwan application serial no. 92103362, filed Feb. 19, 2003.

### BACKGROUND OF THE INVENTION

1. Field of Invention

The present invention relates to a flat display. More particularly, the present invention relates to an active matrix organic electro-luminescence display (AM-OLED).

2. Description of Related Art

Organic electro-luminescence display (OELD) is a type of semiconductor device that can convert electrical energy into photonic energy with relatively high conversion efficiency. In general, OELD has a variety of applications including the light emitting device of an indicator, a display panel and an optical pick-up head of a compact disk player. Due to some special advantages over other types of displays characterized by a lack of viewing angle discrepancy, simple fabrication steps, low production cost, quick response to incoming signals, a wide operating temperature range and a full coloring capacity, OELD is now a dominant display in the multi-media world.

After the development of OELD type devices, a related type of OELD called active matrix OELD has also been introduced to increase overall dimension of the display. The active matrix OELD is fabricated by forming an organic electro-luminescence layer and a cathode layer over a substrate with an array of active devices (for example, thin film transistors). Through the flow of current between the array of pixel electrodes (the anodes) on the substrate and the cathode layer, the organic electro-luminescence layer between the electrodes is activated in a controlled manner to produce a desired image. The method of fabricating a conventional active matrix OELD is explained in greater detail below.

FIG. 1 is a sectional-view showing the structural layout of a conventional active matrix OELD device. FIG. 2 is a magnified view of the area A in FIG. 1. A conventional active matrix organic electro-luminescence display device is constructed over a substrate 100. The OELD structure comprises a gate 102, a gate-insulating layer 104, a channel layer 106, a pair of source/drain terminals 108, a passivation layer 110, a planar layer 112, an anode 116, an organic functional layer 118 and a cathode 120. The gate 102 is formed over the substrate 100 by performing a first masking process. Thereafter, the gate-insulating layer 104 is formed over the gate 102 and the substrate 100. The channel layer 106 is formed over the gate-insulating layer 104 above the gate 102 by performing a second masking process. The source/drain terminals 108 are formed on each side of the channel layer 106 by performing a third masking process. The gate 102, the gate-insulating layer 104, the channel layer 106 and the source/drain terminals 108 together form a thin film transistor.

Thereafter, the passivation layer 110 and the planar layer 112 are sequentially formed over the thin film transistor. Next, contact openings 114 are formed in the passivation layer 110 and the planar layer 112 by performing a fourth masking process. The anode 116 is formed over the planar layer 112 by performing a fifth masking process. The anode 116 and one of the source/drain terminals 108 (for example, the drain terminal) are electrically connected through a contact within contact opening 114. Finally, the organic functional layer 118 and the cathode layer 120 are formed globally over the planar layer 112 and the anode layer 116 to form a complete active matrix OELD device.

As shown in FIG. 2, the organic functional layer 118 directly covers the anode 116. In general, the organic functional layer 118 (for example, an organic light-emitting layer, an electron transmission layer, a hole transmission layer) is fabricated from an organic compound in a thermal evaporation or electron beam evaporation process. Hence, the organic functional layer 118 often has poor step coverage; also, cracks near the edge of the anode 116 are quite common. These cracks frequently lead to a direct short-circuit between the subsequently formed cathode layer 120 and the anode 116. Furthermore, the cracks in the organic functional layer 118 provide a gateway for the entrance of moisture and hence shorten the working life of the device.

In addition, the anode 116 is most likely to be fabricated using indium-tin oxide (ITO) material. During the patterning process, a solution containing nitric acid mixed with hydrochloric acid or an acetic acid solution is often used for etching. The tapering angle after etching the anode 116 further aggravates the problem due to poor step coverage.

### SUMMARY OF THE INVENTION

Accordingly, one object of the present invention is to provide an active matrix organic electro-luminescence display (OELD) device capable of preventing a short circuit between an anode and a cathode layer within the device.

To achieve these and other advantages and in accordance with the purpose of the invention, as embodied and broadly described herein, the invention provides an active matrix organic electro-luminescence display device. The device comprises a substrate, an array of thin film transistors, a dielectric layer, an organic functional layer and a cathode layer. The array of thin film transistors is formed over the substrate. The array of thin film transistors furthermore comprises a plurality of thin film transistors organized into an array, a plurality of anodes corresponding to each thin film transistor and a plurality of scan lines and data lines for driving each thin film transistor. The dielectric layer is formed over the substrate and covers the edge of each anode within the thin film transistor array. The organic functional layer is formed over the thin film transistor array and the dielectric layer and the cathode layer is formed over the organic functional layer.

According to one embodiment of this invention, the thin film transistor can be a bottom gate thin film transistor. The bottom gate thin film transistor has a structure comprising of a gate, a gate-insulating layer, a channel layer and a pair of source/drain terminals. The gate is formed over the substrate. The gate-insulating layer is formed over the substrate covering the gate. The channel layer is formed over the gate-insulating layer above the gate. The source/drain terminals are formed on each side of the channel layer.

If the thin film transistors are bottom gate thin film transistors, the anodes are formed over the gate-insulating layer to connect electrically with corresponding source/drain terminals.

If the thin film transistors are bottom gate thin film transistors, the dielectric layer and the passivation layer can be combined together so that they entirely cover the bottom gate thin film transistors and the edges of all the anodes.

According to the embodiment of this invention, the anode can be fabricated using a material including, for example, indium-tin oxide (ITO) or indium-zinc oxide (IZO). The cathode can be fabricated using a conductive material including, for example, magnesium (Mg), silver (Ag), magnesium-silver-aluminum (MgAg—Al) alloy, lithium-aluminum (LiAl) alloy or lithium-fluorine-aluminum (LiF—Al) compound.

According to one embodiment of this invention, the organic functional layer can be an organic light emitting layer. However, to increase the light-emitting efficiency of the organic electro-luminescence display device, the organic functional layer can have a stack structure that includes a hole injection layer, a hole transmission layer, an organic light-emitting layer and an electron transmission layer, for example. The hole injection layer is formed over the anode layer, the hole transmission layer is formed over the hole injection layer, the organic light-emitting layer is formed over the hole transmission layer and the electron transmission layer is sandwiched between the organic light-emitting layer and the cathode layer.

In the embodiment of this invention, a dielectric layer is used to cover the edges of the anodes so that the anodes are prevented from short-circuiting with the cathode layer. This structure is adaptable to various types of thin film transistor arrays including the two major categories, the amorphous silicon thin film transistor array and the low-temperature polysilicon thin film transistor array (according to channel properties). In addition, the structure is also adaptable to various types of top gate thin film transistor arrays and bottom gate thin film transistor arrays (according to thin film transistor structures).

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a sectional-view showing the structural layout of a conventional active matrix OELD device;

FIG. 2 is a magnified view of the area A in FIG. 1;

FIG. 3 is the circuit diagram of an active matrix organic electro-luminescence display device according to one preferred embodiment of this invention;

FIG. 4 is a top view showing the layout of an active matrix electro-luminescence display device according to one preferred embodiment of this invention; and

FIG. 5 is a cross-sectional view along line A-A of FIG. 4.

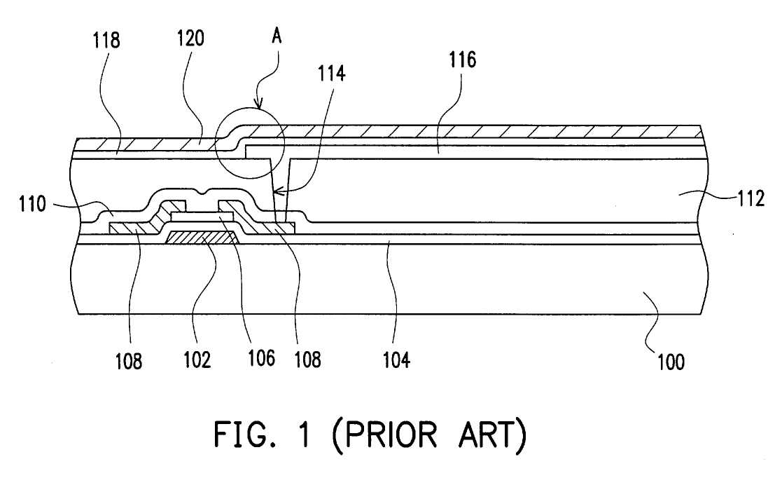

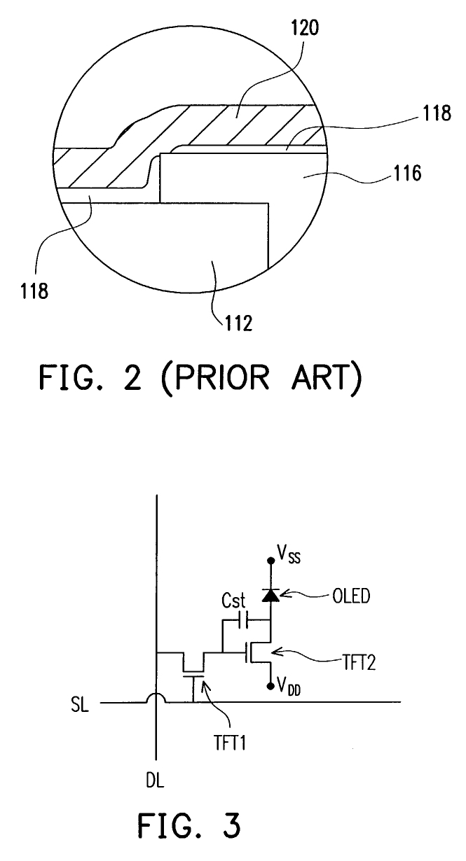

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIG. 3 is the circuit diagram of an active matrix organic electro-luminescence display device according one preferred embodiment of this invention. As shown in FIG. 3, this embodiment deploys an active matrix driving method to improve image contrast and display performance. In the active matrix organic electro-luminescence display device of this invention, each pixel corresponds to two thin film transistors: TFT1 and TFT2. The gate terminal of the thin film transistor TFT1 is electrically connected to a scan line SL. The source terminal of the thin film transistor TFT1 is electrically connected to a data line DL. The drain terminal of the thin film transistor TFT1 is electrically connected to the gate terminal of the thin film transistor TFT2. The source/drain terminals of the thin film transistor TFT2 are coupled to voltage terminals V_{DD} and V_{SS} respectively. A storage capacitor Cst is set up between the gate terminal and the source terminal of the thin film transistor TFT2 for maintaining a voltage difference between the two terminals.

In this embodiment, the thin film transistor TFT1 holds the gate voltage value of the thin film transistor TFT2 for switching the thin film transistor TFT2. Within the scanning period, the thin film transistor TFT2 continuously submits a current to the organic electro-luminescence display (OELD) device. Using this driving method, energy loss through the driving current is minimized and the overall working life of the OELD device is increased.

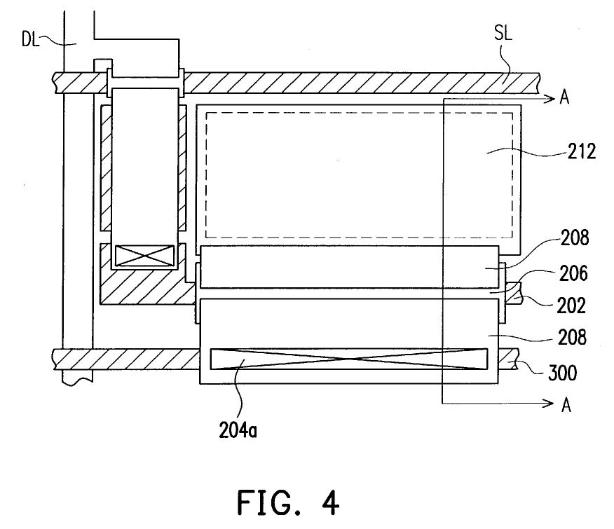

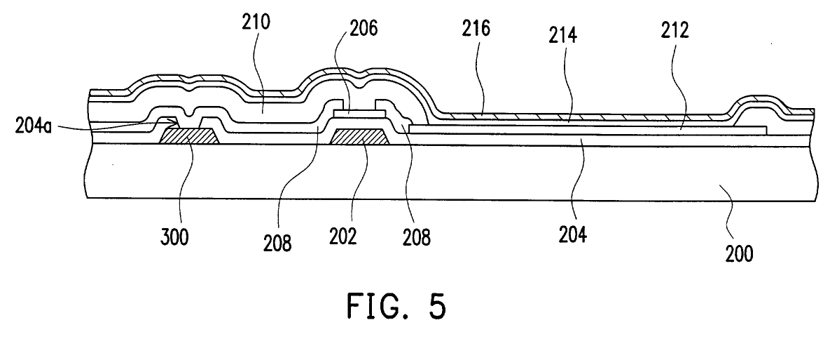

FIG. 4 is a top view showing the layout of an active matrix electro-luminescence display device according to one preferred embodiment of this invention and FIG. 5 is a cross-sectional view along line A-A of FIG. 4. As shown in FIGS. 4 and 5, the active matrix OELD device is constructed over a substrate 200. The active OELD device comprises a gate 202, a gate-insulating layer 204, a channel layer 206, an anode 212, a pair of source/drain terminals 208, a passivation layer 210, an organic functional layer 214 and an cathode layer 216. In addition, wires are also formed at suitable locations over the substrate 200 when the gate 202 is formed. The wires 300 are frequently designed to couple with a terminal providing a voltage V_{DD}.

The anode 212 is fabricated using a material including, for example, indium-tin oxide (ITO) or indium-zinc oxide (IZO). The cathode is fabricated using a conductive material including, for example, magnesium (Mg), silver (Ag), magnesium-silver-aluminum (MgAg—Al) alloy, lithium-aluminum (LiAl) alloy or lithium-fluorine-aluminum (LiF—Al) compound. Furthermore, the organic functional layer is an organic light-emitting layer, for example. However, to increase the light-emitting efficiency of the OELD device, the organic functional layer 214 can have a stack structure that includes a hole injection layer, a hole transmission layer, an organic light-emitting layer and an electron transmission layer, for example. The hole injection layer is formed over the anode layer 212, the hole transmission layer is formed over the hole injection layer, the organic light-emitting layer is formed over the hole transmission layer and the electron transmission layer is sandwiched between the organic light-emitting layer and the cathode layer 216.

In the embodiment of this invention, the gate 202, the wire 300 and the scan line SL are formed over the substrate 200 by performing a first masking process. The gate 202 and the scan line SL are fabricated in steps and are electrically connected to each other. Thereafter, the gate-insulating layer 204 is formed over the gate 202, the wire 300, the scan line SL and the substrate 200. Next, a contact opening 204a is formed over the gate-insulating layer 204 to expose the wire 300 by performing a second masking process. The channel layer 206 is formed over the gate-insulating layer 204 above the gate 202 by performing a third masking process. The anode 212 is formed at a suitable location over the gate-insulating layer 204 by performing a fourth masking process. The source/drain terminals 208 are formed on each side of the channel layer 206 by performing a fifth masking process. One end of the source/drain terminal 208 (for example, the drain terminal) covers the edge of the anode 212 and hence connects electrically with the anode 212. The other end of the source/drain terminal 208 (for example, the drain terminal) extends to the area above the wire 300 and connects with the wire 300 through the contact opening 204a. The gate 202, the gate-insulating layer 204, the channel layer 206 and the source/drain terminals 208 together form a thin film transistor. An array of the thin film transistors and their corresponding anodes 212 together constitute a thin film transistor array.

After forming the thin film transistor array, a dielectric layer 210 is formed over the thin film transistors. The dielectric layer 210 is patterned to expose the anodes 212 by performing a sixth masking process. Note that a portion of the dielectric layer 210 may still cover the edge of the anodes 212 after the patterning process. Finally, the organic functional layer 214 and the cathode layer 216 are formed globally over the dielectric layer 210 and the anodes 212, thereby completing the fabrication of the active matrix OELD device.

As shown in FIG. 4, the active matrix OELD device has a structure comprising a substrate 200, a thin film transistor array (including scan lines SL, data lines DL, gates 202, a gate-insulation layer 204, a channel layer 206 and source/drain terminals 208), a dielectric layer 210, an organic functional layer 214 and a cathode layer 216. The dielectric layer 210 is positioned over the substrate 200 to cover the edge of all anodes 212 within the thin film transistor array. The organic functional layer 214 is positioned over the thin film transistor array and the dielectric layer 210. The cathode layer 216 is positioned over the organic functional layer 214. Since the dielectric layer 210 is fabricated using a material such as silicon oxide or silicon nitride, processes capable of producing good step coverage including, for example, chemical vapor deposition (CVD), sputtering or spin-coating may be used. Thus, even if the tapering angle of between the edges of the anodes 212 is poor, the dielectric layer 210 is still able to cover completely the anodes 212. In other words, with the edges of the anodes 212 protected by the dielectric layer 210, cracks are rarely formed in the subsequently formed organic functional layer 214. Hence, the chance of short-circuiting any anode 212 with the cathode layer 216 is greatly minimized.

Furthermore, as shown in FIG. 4, if the thin film transistors are bottom gate thin film transistors, the dielectric layer 210 and the passivation layer of the device can be combined together so that the bottom gate thin film transistors and the edges of all the anodes are completely covered.

In the embodiment of this invention, a dielectric layer is used to cover the edges of the anodes so that the anodes are prevented from short-circuiting with the cathode layer. Although the aforementioned embodiment uses the bottom gate structure of an amorphous silicon thin film transistor array, as an example, the invention can be applied to other types of devices. For example, the structure of this invention can be adapted to various types of thin film transistor arrays including the two major categories, the amorphous silicon thin film transistor array and the low-temperature polysilicon thin film transistor array (according to channel properties). In addition, the structure of this invention can also be adapted to various types of top gate thin film transistor arrays and bottom gate thin film transistor arrays (according to thin film transistor structures).

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An active matrix organic electro-luminescence display (OELD) device, comprising:
a substrate;
an array of thin film transistors formed on the substrate, wherein the thin film transistor array furthermore comprises a plurality of thin film transistors, a plurality of anodes, a plurality of scan lines and a plurality of data lines;
a dielectric layer formed on the substrate covering the edges of the anodes;
an organic functional layer formed over the thin film transistor array and the dielectric layer; and
a cathode layer formed on the organic functional layer.

2. The active matrix OELD device of claim 1, wherein the thin film transistors comprise bottom gate thin film transistors with each bottom gate thin film transistor having:
a gate formed over the substrate;
a gate-insulating layer formed over the substrate to cover the gate;
a channel layer formed over the gate-insulating layer above the gate; and
a source/drain terminal formed on each side of the channel layer.

3. The active matrix OELD device of claim 2, wherein the anodes are formed over the gate-insulating layer to connect electrically with corresponding source/drain terminals.

4. The active matrix OELD device of claim 3, wherein the dielectric layer furthermore covers the bottom gate thin film transistors.

5. The active matrix OELD device of claim 1, wherein the anodes are fabricated using a material selected from a group consisting of indium-tin oxide and indium-zinc oxide.

6. The active matrix OELD device of claim 1, wherein the organic functional layer comprises an organic light emitting material layer.

7. The active matrix OELD device of claim 1, wherein the organic functional layer furthermore comprises:
a hole injection layer formed over the anode layer;
a hole transmission layer formed over the hole injection layer;
an organic light emitting layer formed over the hole transmission layer; and
an electron transmission layer sandwiched between the organic light emitting layer and the cathode layer.

8. The active matrix OELD device of claim 1, wherein the cathode layer is fabricated using a conductive material selected from a group consisting of magnesium (Mg), silver (Ag), magnesium-silver-aluminum (MgAg—Al) alloy, lithium-aluminum (LiAl) alloy and lithium-fluorine-aluminum (LiF—Al) compound.
